(19) United States
(12) Patent Application Publication
(10) Pub. No.: US 2016/0266176 A1
(43) Pub. Date: Sep. 15, 2016

(54) Range Determination for an Intermediate Bus Architecture Power Supply Controller

(71) Applicant: TELEFONAKTIEBOLAGET L M ERICSSON (PUBL), Stockholm (SE)

(72) Inventors: Torbjörn HOLMBERG, Kalmar (SE); Magnus KARLSSON, Oskarshamn (SE)

(21) Appl. No.: 14/405,460

(22) PCT Filed: Dec. 30, 2013
(86) PCT No.: PCT/EP2013/078115

§ 371 Date: Dec. 4, 2014

(51) Int. Cl. G01R 19/165

(52) U.S. Cl. CPC G01R 19/16528

(57) ABSTRACT

The invention relates to a range determining device for a voltage controller of an intermediate bus voltage (V_{IB}) in an intermediate bus architecture power system, an intermediate bus architecture power system as well as to a method, computer program and computer program product of providing a range within which a controlled intermediate bus voltage in an intermediate bus architecture power system is allowed to vary. The range determining device obtains a range (R3) for the controlled intermediate bus voltage, which range has been determined based on statistical data corresponding to a current time interval of the control, and provides the range to the voltage controller for the voltage controller to control the intermediate bus voltage (V_{IB}) within the determined range in a current time interval.

### TECHNICAL FIELD

The present invention relates to the field of Intermediate Bus Architecture power systems and more specifically to control of an intermediate bus voltage in such systems. The invention more particularly relates to a range determining device for a voltage controller of an intermediate bus in an intermediate bus architecture power system, an intermediate bus architecture power system as well as to a method, computer program and computer program product of providing a range within which a controlled intermediate bus voltage in an intermediate bus architecture power system is allowed to vary.

### BACKGROUND

Power supply of loads such as high-performance ULSI circuits (e.g. processors, ASICs and FPGAs) is demanding, since these types of loads need multiple low supply voltages. These types of loads may be provided in communication networks, such as data communication and telecommunication networks, where the communication networks may furthermore be wireless communication networks such as Long Term Evolution (LTE) or Wideband Code Division Multiple Access (WCDMA) communication networks. The loads may for instance be provided as circuits in a base station (often termed nodeB or enodeB), a Gateway GPRS Support Node (GGSN) or a Serving GPRS Support node (SGSN), where GPRS in an acronym for Global Packet Radio Access.

Because of this there is a need for being able to regulate the supply voltage. In order to provide such regulation as well as for solving other problems associated with power supply of these kinds of loads, there has emerged a so-called Intermediate Bus Architecture (IBA) power supply, which may provide a number of tightly-regulated voltages from an input power source via a two-stage voltage conversion arrangement.

This type of power supply is for instance described in WO 2012/007055 and WO 2010/149205.

It typically comprises one or more Intermediate Bus converters (IBC) connected to an input power supply system as well as to a number of Point-of-Load regulators (POL) via an intermediate voltage bus, where the loads are connected to these POLs.

The structure typically also comprises a Board Power Manager (BPM).

Of these documents WO 2012/007055 does for instance describe how it is possible to control the voltage of the intermediate voltage bus based on the loads.

This is in many ways efficient. However, there may at times be a problem in that the margin within which the control is to be made is static. Hence, the range within which the intermediate bus voltage is controlled is fixed. In practice it is necessary to use such a large range that the full swing of the intermediate bus voltage can be utilized. As a result the power efficiency achieved is not optimized.

There is thus a need for varying the range in which the control voltage at the intermediate bus is allowed to vary in order to obtain a better power efficiency.

### SUMMARY

One object is to provide a flexible range in which the voltage of an intermediate voltage bus in an IBA power supply system is allowed to vary.

This object is according to a first aspect achieved through a range determining device for a voltage controller. The voltage controller generates control signals for controlling an intermediate bus voltage in an intermediate bus architecture power system. The intermediate bus voltage comprises a voltage output from a first stage DC-to-DC power converter to at least one second stage DC-to-DC power converter via an intermediate voltage bus in the intermediate bus architecture power system. The range determining device comprises a processor acting on computer program instructions whereby the range determining device (900) is operative to:

obtain a range for the controlled intermediate bus voltage, which range has been determined based on statistical data corresponding to a current time interval of the control, and
provide the range to the voltage controller for the voltage controller.

Thereby the voltage controller is able to control the intermediate bus voltage within the determined range in the current time interval.

This object is according to a second aspect also achieved through an intermediate bus architecture power system having a voltage controller and a range determining device according to the first aspect.

The object is according to a third aspect achieved through a method of providing a range within which a controlled intermediate bus voltage in an intermediate bus architecture power system is allowed to vary through the control of a voltage controller. The intermediate bus voltage comprises a voltage output from a first stage DC-to-DC power converter to at least one second stage DC-to-DC power converter via the intermediate voltage bus in the intermediate bus architecture power system. The method comprises:

obtaining a range for the controlled intermediate bus voltage, which range has been determined based on statistical data corresponding to a current time interval of the control, and
providing the range to the voltage controller.

Thereby the voltage controller is able to control the intermediate bus voltage within the determined range in the current time interval.

The object is according to a fourth aspect achieved by a computer program for providing a range within which a controlled intermediate bus voltage in an intermediate bus architecture power system is allowed to vary. The computer program comprises computer program code which when run in a range determining device causes the range determining device to

obtain a range for the controlled intermediate bus voltage, which range has been determined based on statistical data corresponding to a current time interval of the control, and
provide the range to the voltage controller for the voltage controller.

Thereby the voltage controller is able to control the intermediate bus voltage within the determined control value range in the current time interval.

The object is according to a fifth aspect furthermore achieved through a computer program product for providing a range within which a controlled intermediate bus voltage in an intermediate bus architecture power system is allowed to vary. The computer program product is provided on a data carrier and comprises the computer program code according to the fourth aspect.

There are several advantages associated with the aspects. The over-time power losses in the system can be reduced when utilizing the statistics. This is due to the fact that the range is dynamic and hence a larger swing of the intermediate bus voltage can be utilized. It also allows faster transitions to a low power loss situation after a low-to-high transient. The use of statistics may furthermore guarantee that the power system is keeping the intermediate bus voltage at the right level. A high level of customization may also be obtained.

According to one variation of the first aspect, the range determining device is further operative to obtain the statistical data associated with the current time interval. In this case the range is obtained through determining the range based on the statistical data.

According to a corresponding variation of the third aspect, the method further comprises obtaining the statistical data associated with the current time interval. Here the obtaining of the range is achieved through determining the range based on the statistical data.

The statistical data may be linked to a reference time interval corresponding to the current time interval. The reference time interval may be linked to the time of day of the current time interval. It may additionally be linked to the day of the week of the current time interval. It may further be linked to the month of the current time interval.

The range may in turn be provided as at least one range limit value. The range limit value may be based on the average intermediate bus voltage of the reference time interval. he range limit value may alternatively or in addition be based on the standard deviation of the intermediate bus voltage in the reference time interval.

The statistical data may be linked to meteorological data corresponding to a meteorological environmental condition of the current time interval.

According to another variation of the first aspect, the range determining device is further operative to apply statistics in a parameterized equation when being operative to obtain a range.

According to a corresponding variation of the third aspect, the obtaining of the range comprises reading a field corresponding to the current time interval in a table with control value range data.

There may further comprise a mathematical model of the intermediate bus architecture power system, where the statistical data is a part of the mathematical model.

According to a further variation of the first aspect, the range determining device when being operative to obtain a range, is further operative to compare results of the control in the intermediate bus architecture power system with corresponding results of processing in the mathematical model, update the mathematical model based on the comparison and obtain the range through estimates of states in the intermediate bus architecture power system provided by the mathematical model According to a corresponding variation of the third aspect, the obtaining of a range comprises applying a control signal from the voltage controller in the mathematical model, comparing results of the control in the intermediate bus architecture power system with corresponding results of processing in the mathematical model, updating the mathematical model based on the comparison and obtaining the range through estimates of states in the intermediate bus architecture power system provided by the mathematical model.

It should be emphasized that the term “comprises/comprising” when used in this specification is taken to specify the presence of stated features, integers, steps or components, but does not preclude the presence or addition of one or more other features, integers, steps, components or groups thereof.

### BRIEF DESCRIPTION OF THE DRAWINGS

Embodiments of the invention will now be explained in detail, by way of example only, with reference to the accompanying figures, in which:

FIG. 1 is a schematic of an intermediate Bus Architecture power system;

FIG. 2 is a schematic of a voltage controller in the IBA power system of FIG. 1;

FIG. 3 is a schematic of a range determining device in the IBA power system of FIG. 1;

FIG. 4 shows an alternative realization of the range determining device;

FIG. 5 shows an example of statistics of intermediate bus voltage variations during a day together with range values determined based on these statistics and used when controlling the bus voltage;

FIG. 6 shows a flow chart of method steps used for estimating load data to be used in providing a range;

FIG. 7 shows a flow chart of method steps in a first embodiment of a method of providing a range;

FIG. 8 shows a flow chart of method steps in a second embodiment of a method of providing a range;

FIG. 9 shows a flow chart of method steps in a third embodiment of the method of providing a range;

FIG. 10 schematically shows the range determining device connected to the system and the voltage controller for implementing a fourth embodiment;

FIG. 11 shows a flow chart of method steps in the fourth embodiment of the method of providing a range;

FIG. 12 shows one alternative placement of the voltage controller and range determining device in an IBC module;

FIG. 13 shows another alternative placement of the voltage controller and range determining device in a PIM module; and

FIG. 14 shows a further alternative placement of the voltage controller and range determining device in a BPM module.

### DETAILED DESCRIPTION

Intermediate Bus Architecture (IBA) power supply systems are of interest to use for supplying power to loads such as high-performance Ultra-Large Scale Integration (ULSI) circuits (e.g. processors, ASICs and FPGAs). These circuits may furthermore be provided in communication networks, such as telecommunication networks, where the communication networks may furthermore be wireless communication networks such as Long Term Evolution (LTE) or Wideband Code Division Multiple Access (WCDMA) communication networks. The loads may for instance be provided as circuits in a base station, often termed nodeB or enodeB, a Gateway GPRS Support Node (GGSN) or a Serving GPRS Support nodes (SGSN), where GPRS in an acronym for Global Packet Radio Access.

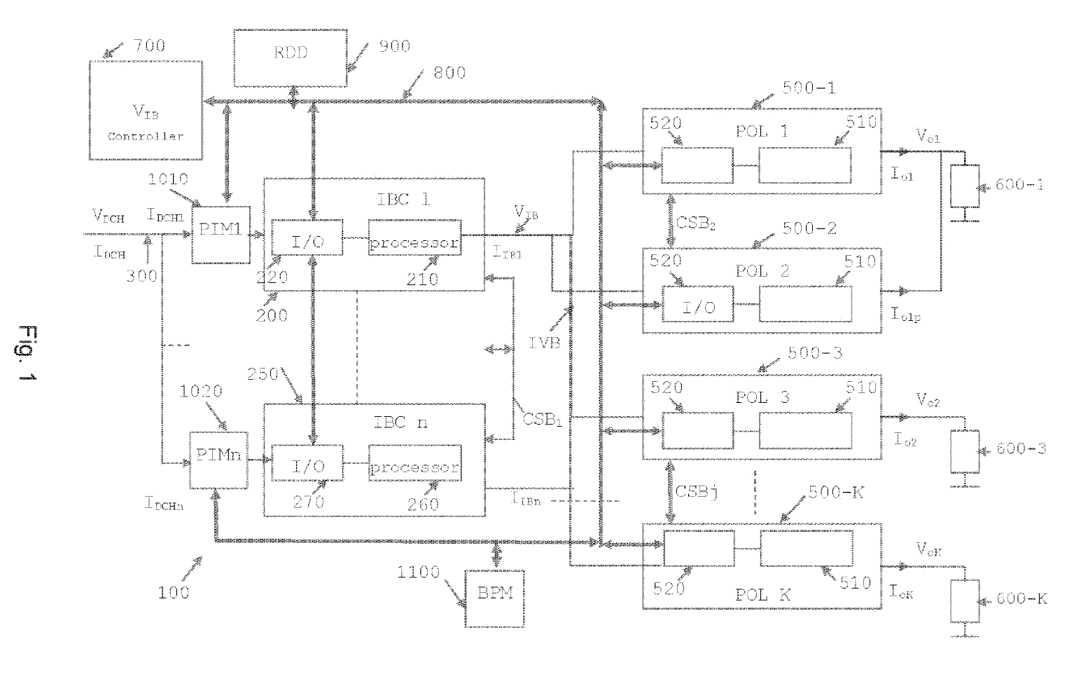

FIG. 1 is a schematic of one such IBA power system 100. The IBA power system 100 in FIG. 1 is a two-stage power distribution network comprising a number n (where n≧1) of parallel-coupled first stage DC/DC converters 200 to 250, whose outputs are connected via an intermediate voltage bus (IVB) to a number K (where K≧1) of second stage DC/DC converters 500-1 to 500-K. The first stage converters 200 to 250 are connected to an input power bus 300 at a voltage V_{DCH}, which is typically at a voltage V_{DCH} between 36-75 V, 18-36 V or 18-60 V. Each first stage converter may furthermore be connected to the input power bus 300 via an optional corresponding filtering unit 1010 and 1020. Such a filtering unit is sometimes referred to as a Power Input Module (PIM). The PIMs (PIM1) 1010 and (PIMn) 1020 are thus connected to the input power bus and each delivers an OR-ed and filtered mains voltage to the corresponding first stage converter.

Each of the first stage DC/DC converters 200 to 250 is preferably an isolated DC/DC converter. A first stage converter is furthermore often referred to as an Intermediate Bus Converter (IBC). An IBA power supply system having such first stage DC/DC converters or IBCs has the advantage of being efficient and cost-effective to manufacture because isolation from the input power bus, which generally requires the use of relatively costly components including a transformer, is provided by a relatively small number of converters (or, where n=1, by a single converter). Alternatively, the IBCs may be non-isolated from the input power bus 300. The IBCs are preferably each implemented in the efficient form of a Switched Mode Power Supply (SMPS), which can be fully regulated or line regulated to convert the input power bus voltage to a lower intermediate bus voltage V_{IB} on the IVB. The IBCs may also be fixed ratio converters.

The IBC 200 may be equipped with a signal processor 210 and an input/output (I/O) interface 220 by which it can be digitally controlled and managed by a voltage controller 700, which will be described in detail below. Control signals and information may be exchanged between the controller 700 and the IBC 200 via an information channel in the form of a Management Bus (MB) 800, which may be parallel or serial. The IBC 200 is capable of adjusting the value of V_{IB} at its output in accordance with the received control signals. The remaining IBCs are similarly configured. For example, the nth IBC 250 has a signal processor 260 and an input/output (I/O) interface 270 by which it can be digitally controlled and managed by a voltage controller 700. Also the PIMs (PIM1) 1010 to (PIMn) 1020 may be connected to the management bus 800.

In general, two or more of the IBCs 200 to 250 may be provided in a current sharing arrangement such that they supply power in parallel to second stage DC-to-DC converters. The information required for current sharing among these IBCs may be exchanged between them via a Current Share Bus CSB₁. In the FIG. 1, there is one Current Share Bus (CSB) in the first stage of the power converter system, although more than one such CSB may be used.

As shown in FIG. 1, the IBCs are connected via the IVB to the inputs of a number K of second stage DC/DC converters 500-1 to 500-K. Each of the plurality of second stage DC/DC converters may be a non-isolated POL regulator in the form of an SMPS. However, a second stage DC/DC converter is not limited to such a converter and may alternatively be a non-switched converter, such as a Low Drop Out (LDO) (linear) regulator. Furthermore, some or all of the second stage DC/DC converters may alternatively be isolated but where isolation is provided by the IBCs, it is advantageous from a cost perspective for the second stage DC/DC converters to be non-isolated. Each POL (k) delivers a regulated output voltage Vₒᵤₜ_{_}ₖ to its load 600-k.

The POL regulators 500-1 and 500-2 may be provided in a current sharing arrangement to deliver power to a common load 600-1. The information required for current sharing is exchanged between these POL regulators via the Current Share Bus CSB₂. However, more generally, in the POL stage there can be numerous Current Share Busses CSB₁, . . . CSBⱼ, and current sharing can be performed between two up to m (where m≦K) POL regulators.

Each of the POL converters is provided with a signal processor 510 and an input/output (I/O) interface 520 by which it can be digitally controlled and managed by the controller 700 via the Management Bus 800.

The IBCs and the POLs may have any type of suitable topology and be of any suitably type. They may thus be Buck, Boost, Buck-Boost, etc.

As can be seen in FIG. 1 there is also a range determining device (RDD) 900 connected to the Management Bus. The role of this is to set a range within which the voltage controller 700 is to operate. This setting of a range will be described in more detail later.

Finally there is an optional Board Power Manager (BPM) 1100 also connected to the Management Bus 800. The BPM 1100 is a controller that controls the power system on a higher level.

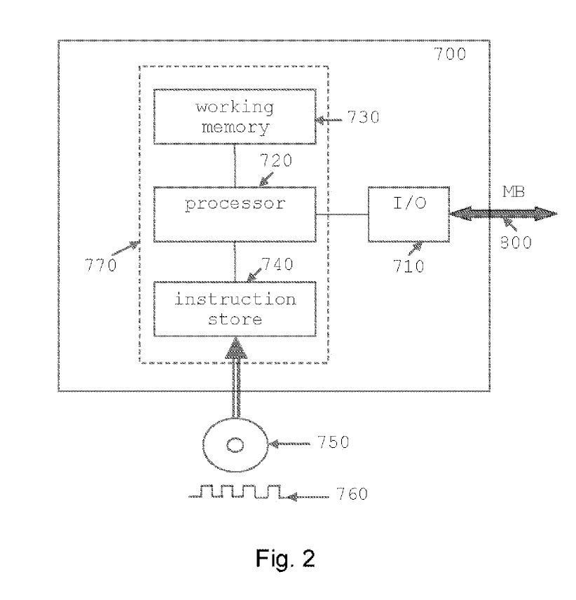

FIG. 2 is a detailed illustration of the voltage controller 700 shown in FIG. 1. The controller 700 comprises an input/output (I/O) or receiving section 710 for receiving information from the IBCs 200 and 250 and preferably also the POL converters 500-1 to 5000-K. The receiving section 710 is connected to the I/O interfaces of the IBCs and the POL converters via the management bus 800, which enables an exchange of information and control signals therebetween. In particular, the receiving section 710 of the controller 700 is configured to receive information concerning the IBCs' operating conditions, including values of their measured input currents I_{DCH1}, . . . I_{DCHn} and preferably their input voltage V_{DCH}. The receiving section may alternatively or additionally be configured to receive values of the output currents I_{IB1}, . . . I_{IBn} and output voltages of the IBCs, preferably together with values of the input voltage V_{DCH}. The receiving section 710 may further be configured to receive information concerning the POL regulators' operating conditions, including their respective measured output voltages Vₒₖ and output currents Iₒₖ.

The receiving section 710 of the voltage controller may furthermore be configured to receive other parameters from the IBCs and POL converters such as their duty cycles, temperatures, system status information for fault monitoring and diagnostics etc. These parameters may be used by the controller for any useful or desirable purpose, for example to implement safety features such as protective cut-offs which ensure that critical parameters such as the component temperatures do not exceed pre-determined thresholds. Alternatively, the controller 700 may forward some or all of the received information to a higher-level entity such as the BPM 1100 or to a system which may be located off the board on which the IBA power system 100 is formed.

As shown in FIG. 2, the voltage controller 700 may further comprise a processor 720, a working memory 730 and an instruction store 740 storing computer-readable instructions which, when executed by the processor 720 cause the processor to perform the processing operations hereinafter described to evaluate a measure of the system efficiency (for example, the current or power input to the IBA system, or the power loss in the system) and to generate control signals for setting the intermediate bus voltage on the basis of this evaluation. The instruction store 740 may comprise a ROM which is pre-loaded with the computer-readable instructions. Alternatively, the instruction store 740 may comprise a RAM or similar type of memory, and the computer readable instructions can be input thereto from a computer program product, such as a computer-readable storage medium 750 such as a CD-ROM, etc. or a computer-readable signal 760 carrying the computer-readable instructions.

In the disclosed variation of the voltage controller 700, the combination 770 comprising the processor 720, the working memory 730 and the instruction store 740 constitutes an efficiency measuring unit and a control signal generator for generating control signals to cause the IBCs to set the intermediate bus voltage. The efficiency measuring unit and the control signal generator will now be described in detail with reference to FIGS. 1 and 2.

As shown in FIG. 2, the voltage controller 700 comprises an efficiency measuring unit 770 in communication with the receiving section 710. The efficiency measuring unit 770 may be arranged to determine a measure of the power input to the IBA power system by determining the current input to the IBCs 200 to 250, or both the input current and the input voltage, using values that have been received by the receiving section 710.

More specifically, the efficiency measuring unit 770 may be configured to calculate, as the measure of the system efficiency, the power input to the IBA power system, Pin, i.e. the product

$${V}_{DCH} {I}_{DCH} = {V}_{DCH} {\sum }_{i = 1}^{n} {I}_{DCHi} .$$

Alternatively, the current input to the IBA power system, I_{DCH}, may be taken as a measure of the system efficiency if the variations in the input voltage V_{DCH} are negligible. As a further alternative, the power loss in the IBA power system may be taken as a measure of the system efficiency; that is, the difference between the power input to the IBA system via the IBCs (i.e. the product I_{DCH}V_{DCH} in FIG. 1) and the power output by the IBA system via the POL converters 500-1 to 500-K (in other words, the sum over all of the POL converters of the respective power outputs as given by product of the output current and voltage,

$${\sum }_{k = 1}^{K} {I}_{ok} {V}_{ok} ) .$$

In any of these cases, the input current I_{DCH} may be determined simply by summing the values of the currents I_{DCHi} which have been measured by the IBCs 200 to 250, such that

$${I}_{DCH} = {\sum }_{i = 1}^{n} {I}_{DCHi} .$$

Alternatively, the total intermediate bus current

$${I}_{IB} = {\sum }_{i}^{ } {I}_{IBi}$$

may be determined by summing the measured values of the currents I_{IBi} output by the IBCs, and used by the efficiency measuring unit 770 in a power loss model of the IBCs to calculate the total input current I_{DCH}. The power loss function P_{IBC} for an IBC can be expressed as a function of the input voltage V_{DCH}, the output voltage V_{IB} and the output current I_{IB}, i.e. P_{IBC}=ƒ_{IBC}(V_{DCH}, V_{IB}, I_{IB}). For better accuracy, it is preferable to also take into account the IBC's temperature T, so that P_{IBC}=ƒ_{IBC}(V_{DCH}, V_{IB}, I_{IB}, T). The input current is then simply I_{DCH}=ƒ_{IBC}/V_{DCH}=g_{IBC}(V_{DCH}, V_{IB}, I_{IB}, T). The function ƒ_{IBC} and/or g_{IBC} can be obtained by power loss measurements of physical IBCs and modelled as a polynomial, typically of second order, whose coefficients can be obtained by Least Squares regression analysis, for example. Of course, other mathematical models may be used although polynomial functions are easy to calculate and are therefore preferred. Instead of Least Squares, other regression tools can be used, such as Least Absolute Deviation.

As noted above, the voltage controller may further comprise a control signal generator 770. The control signal generator 770 is arranged to generate, on the basis of the efficiency measure values determined by the efficiency measuring unit, control signals for use by the IBCs 200 to 250 to set the intermediate bus voltage V_{IB}. The control signal generator may transmit the generated control signals to the IBCs via the MB 800, preferably using the Power Management Bus (PMBus) protocol, at a timing determined thereby or in response to control signal requests made by the IBCs. The IBCs are configured to adjust the intermediate bus voltage using the received control signals. It may more particularly employ a set and optimise algorithm or a current margin algorithm Details of control using two different set and optimise algorithms and a current margin algorithm may be found in WO 2012/007055.

The above-described operations of the voltage controller 700 all provide regulation of the intermediate bus voltage V_{IB} for an optimized system efficiency based on the actual load conditions. The range within which the above described intermediate bus voltage is controlled has traditionally been fixed. In practice it is then typically necessary to use such a large range that the full swing of the V_{IB} can be utilized. As a result the power efficiency achieved is not optimized.

It would therefore be of interest to obtain a control where a better power efficiency is obtained.

This could be done if statistics or trends related to the load of the IBA power system is used for influencing the control.

This problem is addressed with the use of the range determining device 900, which provides a range within which the intermediate bus voltage is allowed to be controlled by the voltage controller, which range varies based on statistical load changes.

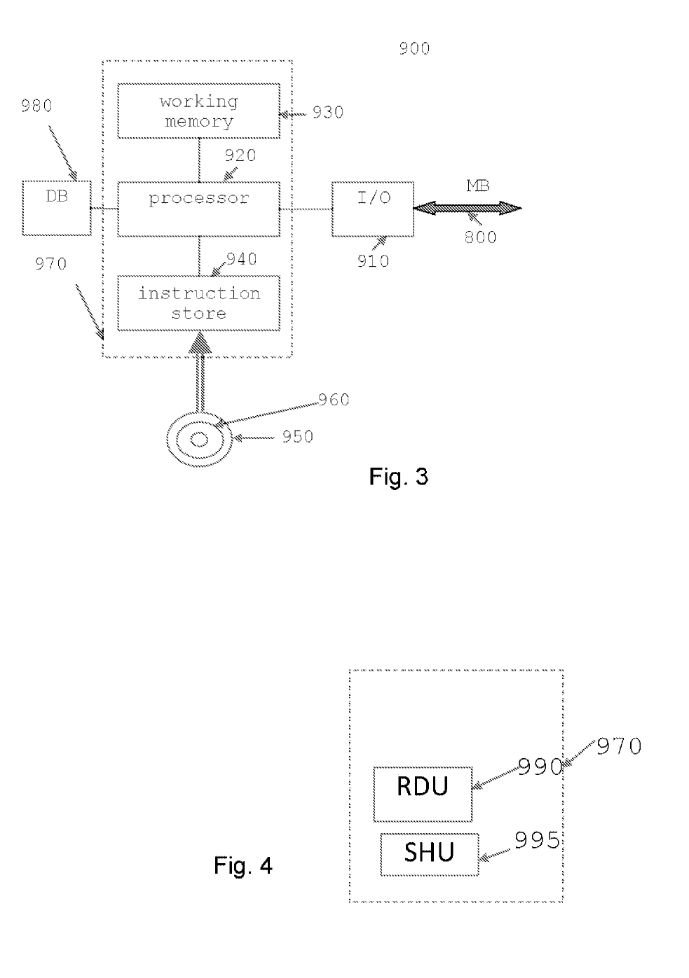

FIG. 3 is a detailed illustration of a possible realization of the range determining device 900 shown in FIG. 1. The range determining device 900 comprises an input/output (I/O) unit 910 for providing a range to the voltage controller 700. It may also receive statistical data from a statistics providing device. The statistical data may comprise statistical load data having been determined historically by the statistics providing device. The statistical load data may furthermore comprise statistical intermediate bus voltages. The statistics may furthermore be organized according to time intervals in which the traffic statistics were collected, which time intervals may be termed reference time intervals.

As is shown in FIG. 3, the range determining device 900 may further comprise a processor 920, a working memory 930 and an instruction store 940 storing computer-readable instructions which, when executed by the processor 920 cause the processor to perform the processing operations hereinafter described to determine a range for the voltage controller 700. The processing operations may also comprise the determining of range defining data based on the statistics, where the range defining data may comprise determining data directly used for forming a range, such as limits of the range or data that may be used for forming a range after some further processing, such as mean values or averages and standard deviation of intermediate bus voltages. These latter processing operations may also be termed statistics handling operations. The instruction store 940 may comprise a ROM which is pre-loaded with the computer-readable instructions. Alternatively, the instruction store 940 may comprise a RAM or similar type of memory, and the computer readable instructions can be input thereto from a computer program product, such as a computer-readable storage medium 950 such as a CD-ROM, etc. with the computer program instructions 960.

In the disclosed variation of the range determining device 900, the combination 970 comprising the processor 920, the working memory 930 and the instruction store 940 constitutes a range determining unit for providing a range to voltage controller and optionally also a statistics handling unit.

The processor 920 is also connected to a database DB 980 comprising statistical data such as statistical load data. The statistical data may comprise data that has been measured and input by an operator. Alternatively the power system may itself measure and/or update statistical data, for instance continuously, so that a database with historical statistical data is provided. This statistical data may be the statistical intermediate bus voltages as for instance measured by the POLs or reported by the voltage controller. The statistical data may additionally or instead comprise the results of statistical calculations made on the historical intermediate bus voltages.

The processor when acting on above-mentioned program code thus implements a range determining function, which uses statistical load data for determining a range within which the intermediate bus voltage is to be controlled as well as possibly a statistics handling function for estimating load data on which a range may be determined.

An alternative block schematic of the range determination device is shown in FIG. 4, which shows the device 900 comprising the range determining unit (RDU) 990 and the statistics handling unit (SHU) 995.

The statistical data may be provided in the database 980. The provision of the database 980 within the range determining device 900 is optional. It may as an alternative be provided somewhere else in the system and accessed via the bus 800. It may thus be accessed by the range determining unit (RDU) 990 as well as by the statistics handling unit (SHU) 995. Statistics may alternatively be a part of system model, i.e. a mathematical model of intermediate bus system comprising the first and second converter stages. It may also be a part of a parameterised equation.

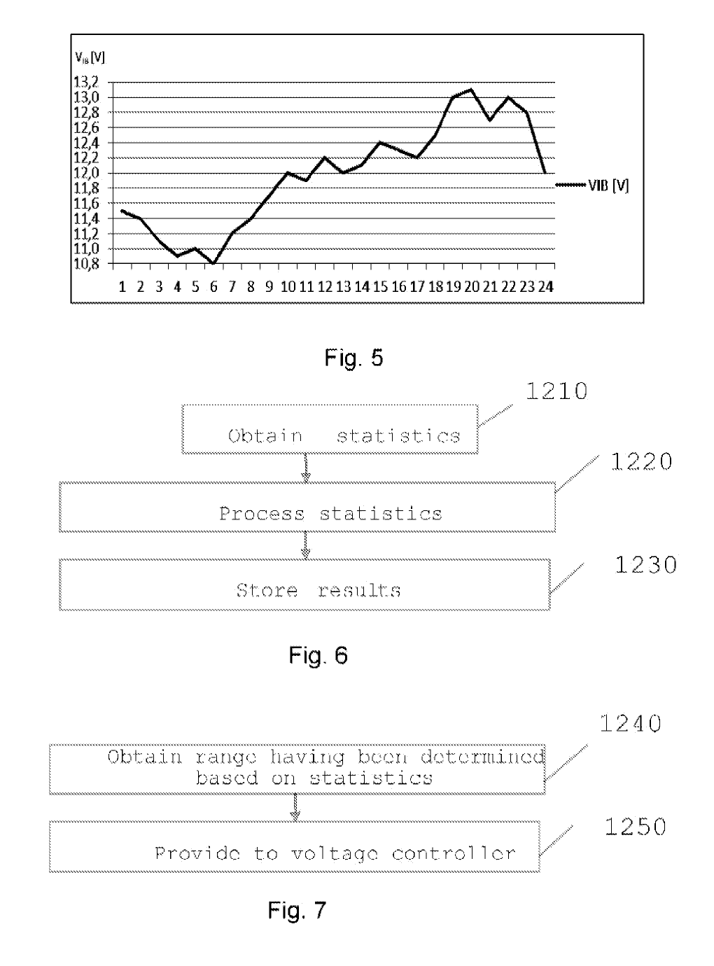

How a range may be determined will now be described with reference also being made to FIG. 5, which shows statistical variations of the intermediate bus voltage together with ranges that have been determined in relation to such statistical variations and to FIG. 6, which shows a number of method steps for processing statistical load data or load variations based on statistical traffic variations.

The traffic in a data communication network or telecommunication network, such as but not limited to LTE or WCDMA, may vary considerably depending on for instance time of day and type of day. If the IBV power supply system is provided for power supply of loads in such a network also the loads will show similar changes. It may therefore be of interest to use statistics in the control. As the voltage controller controls the intermediate bus voltage it would therefore be of interest to use statistics of this intermediate bus voltage. These statistics may then be used to influence the range within which the intermediate bus voltage is allowed to vary.

It is for instance possible that the intermediate bus voltage is measured and reported, for example by the POLs or the IBCs, or that the desired intermediate bus voltage to be obtained via the control is reported, for example by the voltage controller 700, to the statistics handling unit (SHU) 995, which then stores it in the database 980.

It is thus possible to obtain an intermediate bus voltage statistics based on which a range within which the intermediate bus voltage is allowed to be controlled. FIG. 5 also shows a number of ranges having been determined for the statistical variations of the intermediate bus voltage.

FIG. 5 shows an example of statistics of a weekday. It is also possible to consider statistics of a week, where the traffic may differ between weekdays and weekends. Therefore also the intermediate bus voltage may vary accordingly. It is also possible to consider statistics separately for each day of the week. It is also possible that the traffic on a yearly basis, i.e. per month as well as based on different weather conditions is considered in the statistics.

The traffic situation for a weekend may for instance differ from the traffic situation on a weekday. Even if it is not measured, it is easy to image that the traffic situation on nice summer day will be different from a windy and cold winter day. Also these differences will be apparent in the variations of the intermediate bus voltage. The collected statistical values may thus in addition to being time dependent also have a meteorological dependency. Statistical data being collected may thus be linked to meteorological data.

It is thus possible to use statistics for a typical weekday, weekends, a nice summer day, a windy and cold winter day, etc. as input for determining ranges.

According to some aspects statistical characteristics of the estimated intermediate bus voltage, such as standard deviation and average, are used for determining a range. It is possible to use also other types of statistical measures such as variance and median.

As an example, it is possible to predict the average and standard deviation of the load situation on a piece of specific equipment, on a specific place, at a specific day of the year, and at a specific weather condition based on the statistical traffic variation data. Specifically, the range within which the intermediate bus voltage V_{IB} is to be operated can vary with the statistics. The range may then be a range within which the intermediate bus voltage is allowed to vary during a current time interval. In FIG. 5, the idea with different ranges for V_{IB} is illustrated. These ranges may be provided as actual maximum and minimum regulation levels of the V_{IB} voltage.

If as an example one range per hour is used, then it is possible to have 24 different ranges for a day, denoted, R1, R2, . . . , R24. For example, at 3 o'clock in the morning the range to use is R3, at 5 o'clock R5 is used, and so on. A current time interval of the control is in this example thus an hour during a weekday.

The ranges (in this case R1, R2, . . . , R24) may include information about minimum, maximum or both minimum and maximum values of the intermediate bus voltage V_{IB}. Typically, the upper and lower limit values in each time interval may be calculated from statistics using the following expressions:

V_{IBmin}=V_{IBavg}−n*V_{IBstd} (1)

V_{IBmax}=V_{IBavg}+n*V_{IBstd} (2)
where, V_{IBavg} is the average V_{IB} level in each time interval, V_{IBstd} is the standard deviation of the V_{IB} levels in each time interval and n is a degree of confidence, where n=1, 2, 3 (or more if higher confidence interval than six sigma is requested).

As can be seen range may thus be provided as at least one range limit value, which range limit value is based on the average intermediate bus voltage of the reference time interval. It may additionally or instead be based on the standard deviation of the intermediate bus voltage in the reference time interval.

The statistics handling unit (SHU) 995 may therefore obtain statistics such as statistics of intermediate bus voltage variations, step 1210, for instance from a traffic statistics providing device, processes the statistics, step 1220, such as determines statistical values of the intermediate bus voltage for various time intervals in which the statistics are collected, like mean and median values and standard deviation as well as even determining ranges, which intervals are reference time intervals. It may possibly also determine ranges based on the statistical values. The results of the processing may then be stored in one or more corresponding tables in the database 980 relating to the reference time intervals, step 1230. The statistics providing device may be a POL, IBC or the voltage controller which regularly sends the intermediate bus voltage values to the statistics handling unit (SHU) 995, which when having received the statistical data performs the processing and stores the result of in the database 980. Alternatively another entity, such as the BPM, has all the statistics data, i.e. the intermediate bus voltage values of a reference time interval and sends them to the statistics handling unit (SHU) 995 for the processing.

The ranges determined for the different time intervals may thus be provided in tables. However that may also be provided as a part of a parameterized function. As an alternative the statistical data used for determining ranges may be provided as a part of a mathematical model of the IBA power supply system.

The statistical intermediate bus voltage levels as well as the ranges may thus be determined by the statistics handling unit (SHU) 995. This unit was above described as being a part of the range determining device 900. As an alternative this unit 995 may be provided outside of the range determining device 900, for instance in the BPM 1100.

An example of how a table may look for a week day is here:

TABLE 1

| | | | | | | Con- |
|---|---|---|---|---|---|---|
| | | | | Statistics | | fidence |
| Time | | | | based on | | degree |
| inter- | Range | Range used | | existing data | | wanted |
| val | name | V_{IBmin} | V_{IBmax} | V_{IBavg} | V_{IBstd} | n |
| 1^{st} | R1 | =V_{IBavg1 -} | =V_{IBavg1 +} | V_{IBavg1} | V_{IBstd1} | 3 |
| hour | | n * V_{IBstd1} | n * V_{IBstd1} | | | |
| of the | | | | | | |
| day | | | | | | |
| 2nd | R2 | =V_{IBavg2 -} | =V_{IBavg2 +} | V_{IBavg2} | V_{IBstd2} | 3 |
| hour | | n * V_{IBstd2} | n * V_{IBstd2} | | | |
| of the | | | | | | |
| day | | | | | | |
| . . . | . . . | . . . | . . . | . . . | . . . | . |
| 24th | R24 | =V_{IBavg2 -} | =V_{IBavg2 +} | V_{IBavg24} | V_{IBstd24} | 3 |
| hour | | n * V_{IBstd24} | n * V_{IBstd24} | | | |
| of the | | | | | | |
| day | | | | | | |

Now a first embodiment will be described with reference also being made to FIG. 7, which shows a flow chart of a method of providing a range being performed by the range determining device.

The range determining unit (RDU) 990 obtains a range for the controlled intermediate bus voltage, which range has been determined based on the statistical data corresponding to a current time interval of the control, step 1240. The current time interval is here a interval within which the voltage controller 700 currently performs control. The obtaining of a range may be performed through the range determining unit (RDU) 990 fetching a range corresponding to the current time interval from the database 980. If the current time is 01.30 a.m. on a Wednesday in December, the current time interval may be between 01 and 02 a.m. on this day. In this case the range is based on statistics gathered in a corresponding reference time interval, i.e. a time interval representing the same time in a corresponding table, which table may be a weekday table, a table for the same day of the week at a table for weekdays or Wednesdays in December etc. The reference time interval may thus be linked to the time of day H of the current time interval, the day of the week of the current time interval and the month of the current time interval. This range data may be obtained from one or more range fields in a corresponding table in the database. It can in the time example give above that the range R3 is obtained in this way. Alternatively a parameterised equation, with the parameter variable according to the current time interval is used or a system model of the time interval for the current time interval.

Once a range has been obtained in any of the above mentioned ways, this range is then provided to the voltage controller 700, step 1250, for the voltage controller to control the intermediate bus voltage (V_{IB}) within the determined range in the current time interval. Thereafter the voltage controller (700) applies the range in the control.

In this way there a range determined based on the statistical traffic variations and thereby a more efficient control is obtained.

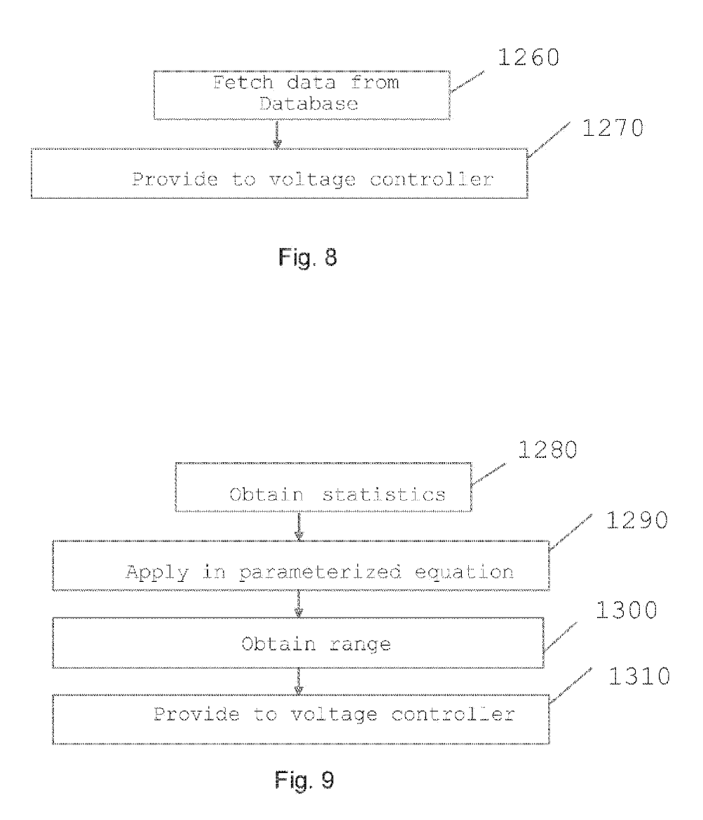

Now a second embodiment will be described with reference also being made to FIG. 8, which shows yet a flow chart of a number of steps that are used for determining the range. In this case the table based solution is used.

There is thus at least one table in the database 980, which table as an alternative may be provided by the BPM 1100. It should however be realized that an arbitrary number of tables can be implemented. In the most simple case, only one table is used, which may be a table that is applicable for every day. There is in this case no distinction being made between weekdays and weekends, months or different weather conditions. Furthermore, the data in the table may be regularly updated as new statistics is collected. The table may thus comprise the ranges and only the ranges. As an alternative it is possible that the statistical values such as average and standard deviations of the intermediate bus voltages calculated for the reference time interval are provided in the table and the range determining unit (RDU) 990 will then calculate the ranges based on these values. In a somewhat advanced case, one table for weekdays and another one for weekends can be used. In a very advanced case, a large number of tables can be used, and the one to use is selected using data about actual time, day, week, month or event (which can be a certain day as for example New Years Eve, a windy and cold winter day, or a certain situation like a catastrophe). A table may thus also be linked to meteorological data and ranges of a reference time interval linked to the current time interval may be fetched if there is meteorological environmental condition present during the current control, which meteorological condition corresponds to meteorological data associated with the table.

Based on which the current time interval is, for instance between 11 and 12 am, the range determining unit (RDU) 990 fetches data from at least one corresponding field of a table, step 1260, where the data being fetched is related to the reference time interval. It may here fetch an upper limit of the range in an upper range field and a lower limit of the range in a lower range field and then provide the range data to the voltage controller, step 1270. It may thus read a field in a table of the database, which field corresponds to the current time interval and comprises control value range data Alternatively, it may collect the average and standard deviations from two fields in the table and determine the range based on these values.

This embodiment has the advantage of being fast, since it is based on fetching pre-calculated range values or calculates the ranges easily based on previously made statistical calculations.

Thereafter the range determining unit (RDU) 990 sends the range data to the voltage controller 700 for being used in the control of the intermediate bus voltage, step 1270.

Now a third embodiment will be described with reference also being made to FIG. 9. In this case the range determining unit 990 provides a set of parameterised equations comprising at least one equation.

An equation in the set may be an equation for determining a lower range limit and may be based on equation (1) above. Another equation in the set may be provided for determining an upper range limit and may be based on equation (2) above. A further equation in the set may be an equation for determining standard deviation and yet another equation in the set may be an equation for determining an average. In this case the database may only comprise intermediate bus voltages in the various reference time intervals, which intermediate bus voltage may be the above mentioned estimated, measured or desired intermediate bus voltages.

In this third embodiment statistics is fetched form the database, step 1280, such as the intermediate bus voltages of a reference time interval or statistical data such as averages and standard deviation of the intermediate bus voltages in the reference time interval corresponding to the current time interval. The data is then entered into the equations, step 1290, and a range obtained therefrom, step 1300, which range is then provided to the voltage controller 700, step 1310.

This has the advantage of reducing pre-processing performed by the statistics handling unit (SHU) 995 at the expense of some additional processing by the range determining unit (RDU) 990.

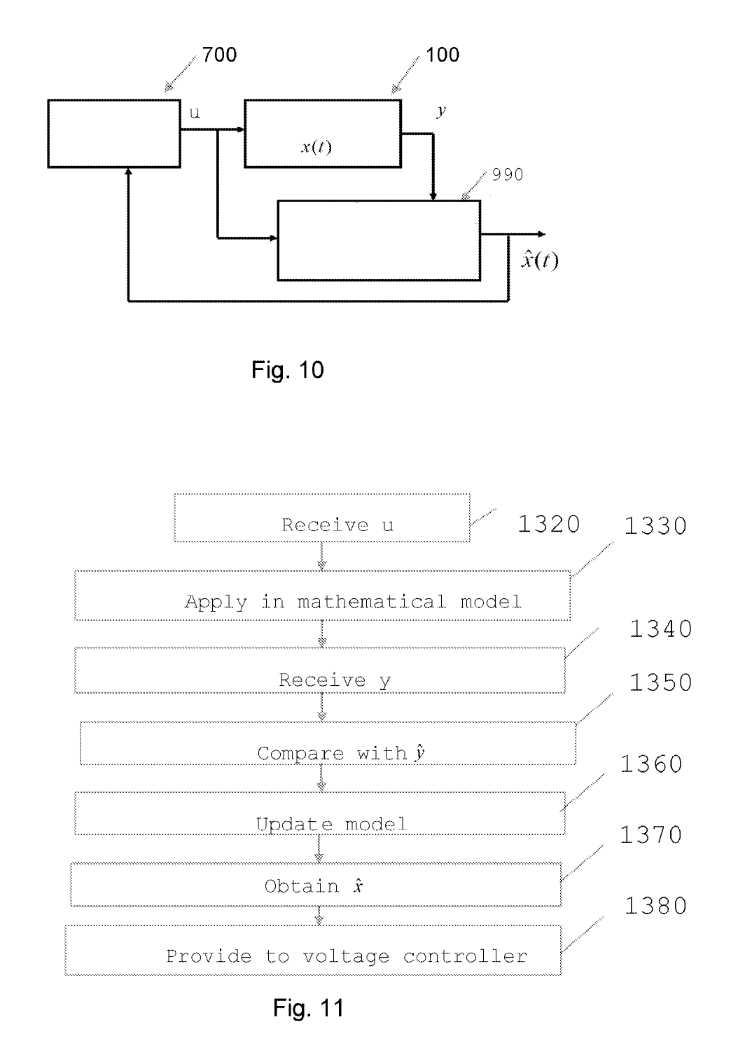

Now a fourth embodiment will be described with reference being made also to FIGS. 10 and 11, where FIG. 10 schematically shows the range determining unit (RDU) 990 connected to the system 100 and the voltage controller 700 and FIG. 14 shows a flow chart of method steps in the method of providing a range performed by the range determining unit 990.

This embodiment is based on a recursive filter or algorithm, for example, Kalman filtering, and the use of an observer providing a mathematical model of the IBA power supply system, which observer is provided through the range determining unit (RDU) 990. The IBA power supply system 100 may be considered as a black box into which an input signal u is provided and which provides a number of outputs y, such as intermediate bus voltages and currents. The range determining unit (RDU) 990 with the observer receives the same input signal u. The system is made up, of a number of unknown states x and the mathematical model provides estimates of these states \hat{x}. The observer therefore also provides estimated output signals ŷ. The observer furthermore provides a number of equations:

\hat{x}ₖ₊₁=A*\hat{x}ₖ+L[y(k)−\hat{y}(k)]+B*uₖ (3)

yₖ=C*\hat{x}ₖ+D*uₖ (4)

where A, B, C, D and L are matrices with desirable system constants of the model and k represents an instance in time. An estimated state \hat{x} representing the range may then be obtained through knowledge about the matrices A, B, C D and L. As the inputs and outputs are known it is then possible to obtain estimates of the states, which are refined through iteration Here the system constants comprise settings obtained from the traffic load statistics. It can be seen from the equations above that it is possible to obtain continuously updated estimated states \hat{x} for forming the range.

In the method of the fourth embodiment, the range determining unit (RDU) 990 receives the control signal u from the voltage controller, step 1320. This control signal, which is also applied to the real IBA power supply system 100 by the voltage controller, is then inserted into the mathematical model of the IBA power supply system, step 1330. Thereafter the range determining unit (RDU) 990 receives the processing results y, which may be the measured intermediate bus voltages and/or currents, step 1340. The range determining unit (RDU) 990 thereafter compares the real processing results y with estimated processing results ŷ in the model, step 1350, and updates the model, step 1360, which updating may comprise refining the system state or states \hat{x} corresponding to the range. Thereafter the range determining unit (RDU) 990 fetches the current estimated state from the model, step 1370, and then provides the state to the voltage controller, step 1380, for setting the range.

Such a range determination adapts continuously ongoing, where the system information vectors may be changed depending on the current time interval, day, month etc.

The advantage with an observer solution is that the “update of statistics” is performed continuously by measurement of appropriate signals, in this case the V_{IB} voltage and the V_{IB} current. It requires that a model is created from the statistics and historic data measured.

As a consequence of the use of statistically based ranges for the intermediate bus voltage, low-to-high load transient voltages can be handled in a more power efficient way. So instead of, as was done previously, always changing to nominal output voltage, V_{IBnom}, in case of such a load transient the intermediate bus voltage can be configured to go to the current V_{IBmax} level through the control of the voltage controller 700. If V_{IBmax} is lower than V_{IBnom} the system power efficiency can be improved.

After a low-to-high transient event, the V_{IB} can be reduced to the V_{IBavg} level faster than it can be without knowing the statistics. Hence a time, tᵣₑₜᵤᵣₙ_{_}ₜₒ_{_}_{avg}, may be introduced in the voltage controller 700 and which can be used as the delay time from a transient event occurs to the time the V_{IB} it is allowed to return to the V_{IBavg} level. In a similar way a time, tᵣₑₜᵤᵣₙ_{_}ₜₒ_{_}ₘᵢₙ, may be introduced in the voltage controller 700. This time can be used to configure the delay time from a transient event occurs to the time the V_{IB} it is allowed to return to the V_{IBmin} level.

The invention has a number of advantages. The over-time power losses in an IBA board power system can be reduced when utilizing the statistics about the load situations (traffic situations for a base station or a data communication device) during a day, week, month or the time interval of interest. This is due to the fact that the range is dynamic and hence a larger swing of V_{IB} can be utilized. It also allows faster transitions to a low power loss situation after a low-to-high transient. The statistics and the desired level of confidence guarantee that the power system is keeping the V_{IB} at the right level. Finally, a higher level of customization is also obtained.

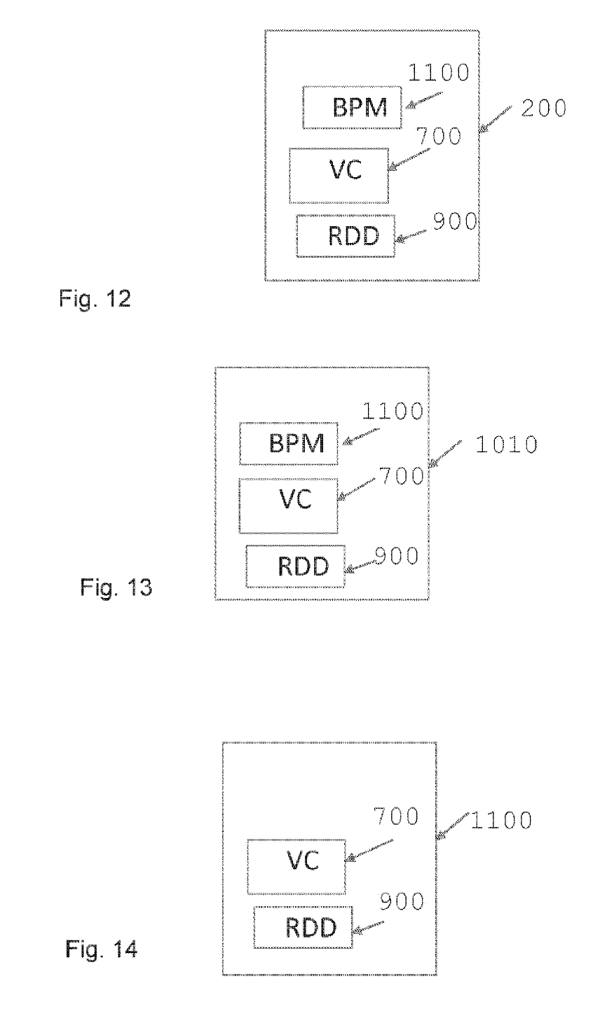

The range determining device RDD and the voltage controller VC were above described as separate standalone devices. They may as an alternative be provided in the same device. The range determining device may furthermore be provided in a number of the previously described entities. It may for instance be provided in a PIM unit, in an IBC unit or in a BPM unit. The voltage controller may additionally or instead be provided in the same entity. Furthermore, the range determining device, the voltage controller and the BPM unit may be provided together. FIG. 12 schematically shows the range determining device (RDD) 900, voltage controller (VC) 700, and the BPM 1100 provided in an IBC unit 200. FIG. 13 schematically shows the range determining device (RDD) 900, voltage controller (VC) 700 and BPM 1100 provided in a PIM unit 1010 and FIG. 14 schematically shows the range determining device 900 and voltage controller 700 provided in the BPM 1100.

The range determining device may furthermore be considered to form means for obtaining a range for the controlled intermediate bus voltage, which range has been determined based on statistical data corresponding to a current time interval of the control and means for providing the range to the voltage controller (700) for the voltage controller to control the intermediate bus voltage (V_{IB}) within the determined range in the current time interval.

The range determining device may further be considered to form means for obtaining the statistical data associated with the current time interval. Here the means for obtaining a range comprises means for determining the range based on the statistical data.

The means for obtain a range may further be considered to comprise means for reading a field in a table of a data storage, where this field corresponds to the current time interval and comprises control value range data.

The means for obtain a range may further be considered to be means for applying statistics in a parameterized equation.

The means for obtaining a range may further be considered to comprise means for comparing results of the control in the intermediate bus architecture power system with corresponding results of processing in the mathematical model, means for updating the mathematical model based on the comparison and means for obtaining estimates of states in the intermediate bus architecture power system provided by the mathematical model as the range.

While the invention has been described in connection with what is presently considered to be most practical and preferred embodiments, it is to be understood that the invention is not to be limited to the disclosed embodiments, but on the contrary, is intended to cover various modifications and equivalent arrangements. Therefore the invention is only to be limited by the following claims.

1-23. (canceled)

24. A range determining device for a voltage controller that is configured to generate control signals for controlling an intermediate bus voltage in an intermediate bus architecture power system, the intermediate bus voltage comprising a voltage output from a first stage DC-to-DC power converter to at least one second stage DC-to-DC power converter via an intermediate voltage bus in the intermediate bus architecture power system, the range determining device comprising a processing circuit configured to:
obtain a range for the controlled intermediate bus voltage, which range has been determined based on statistical data corresponding to a current time interval of the control; and
provide the range to the voltage controller for the voltage controller to control the intermediate bus voltage within the determined range in the current time interval.

25. The range determining device according to claim 24, wherein the processing circuit is configured to obtain said statistical data associated with the current time interval and to determine the range based on the statistical data.

26. The range determining device according to claim 24, wherein the statistical data is linked to a reference time interval corresponding to the current time interval.

27. The range determining device according to claim 26, wherein the range is provided as at least one range limit value.

28. The range determining device according to claim 27, wherein the range limit value is based on the average intermediate bus voltage of the reference time interval.

29. The range determining device according to claim 27, wherein the range limit value is based on the standard deviation of the intermediate bus voltage in the reference time interval.

30. The range determining device according to claim 26, wherein the reference time interval is linked to the time of day of the current time interval.

31. The range determining device according to claim 30, wherein the reference time interval is linked to the day of the week of the current time interval.

32. The range determining device according to claim 31, wherein the reference time interval is linked to the month of the current time interval.

33. The range determining device according to claim 24, wherein the statistical data is linked to meteorological data corresponding to a meteorological environmental condition of the current time interval.

34. The range determining device according to claim 24, wherein the processing circuit is configured to obtain the range based on reading a field in a table of a data storage, said field corresponding to the current time interval and comprising control value range data.

35. The range determining device according to claim 24, wherein the processing circuit is configured to obtain the range by applying the statistical data in a parameterized equation.

36. The range determining device according to claim 24, wherein the processing circuit is configured to obtain the range using a mathematical model of the intermediate bus architecture power system, where the statistical data is a part of the mathematical model, based on being configured to:
compare results of the control in the intermediate bus architecture power system with corresponding results of processing in the mathematical model;
update the mathematical model based on the comparison; and
obtain the range through estimates of states in the intermediate bus architecture power system provided by the mathematical model.

37. The range determining device according to claim 24, wherein the processing circuit comprises a processor and an associated memory storing computer program instructions the execution of which by said processor configures the processor to carry out the method of claim 24.

38. A method of providing a range within which a controlled intermediate bus voltage in an intermediate bus architecture power system is allowed to vary through the control of a voltage controller, the intermediate bus voltage comprising a voltage output from a first stage DC-to-DC power converter to at least one second stage DC-to-DC power converter via the intermediate voltage bus in the intermediate bus architecture power system, the method comprising:
obtaining a range for the controlled intermediate bus voltage, which range has been determined based on statistical data corresponding to a current time interval of the control; and
providing the range to the voltage controller for the voltage controller to control the intermediate bus voltage within the determined range in the current time interval.

39. The method according to claim 38, wherein obtaining the range comprises:
obtaining said statistical data associated with the current time interval;
determining the range based on the statistical data.

40. The method according to claim 38, wherein the statistical data is linked to a reference time interval corresponding to the current time interval.

41. The method according to claim 40, wherein the range is provided as at least one range limit value.

42. A method according to claim 38, wherein obtaining the range comprises reading a field from a stored table, said field comprising control value range data and corresponding to the current time interval.

43. The method according to claim 38, wherein obtaining the range comprises applying said statistical data in a parameterized equation.

44. The method according to claim 38, wherein obtaining the range comprises:
applying a control signal from the voltage controller in a mathematical model of the intermediate bus architecture power system, where the statistical data is a part of the mathematical model;
comparing results of the control in the intermediate bus architecture power system with corresponding results of processing in the mathematical model;
updating the mathematical model based on the comparison; and
obtaining the range through estimates of states in the intermediate bus architecture power system provided by the mathematical model.

45. A non-transitory computer-readable medium storing a computer program comprising program instructions for execution by a processing circuit operative as a range determining device and associated with a voltage controller that is configured to generate control signals for controlling an intermediate bus voltage in an intermediate bus architecture power system, said computer program comprising program instructions to configure the processing circuit to:
obtain a range for the controlled intermediate bus voltage, which range has been determined based on statistical data corresponding to a current time interval of the control; and
provide the range to the voltage controller for the voltage controller to control the intermediate bus voltage within the determined control value range in the current time interval.
